(19) United States
(12) Patent Application Publication
(10) Pub. No.: US 2019/0272008 A1
(43) Pub. Date: Sep. 5, 2019

(54) SSD Module For Mounting In A HDD Bay Of A Rack Server

(71) Applicant: HoneycombData Inc., Santa Clara, CA (US)

(72) Inventor: Shen Ping, Santa Clara, CA (US)

(21) Appl. No.: 15/909,804

(22) Filed: Mar. 1, 2018

(51) Int. Cl. G06F 1/18; H05K 7/14

(52) U.S. Cl. CPC G06F 1/187; H05K 7/1492; H05K 7/1489

(57) ABSTRACT

A modular SSD inserts within a bay in a rack server that may also accommodate a standard modular HDD. The modular SSD includes first and second PCBs each having SSD modules mounted thereto. For example, four SSD modules on each PCB. The first PCB includes a data connector at a first end that connects to a connector at the first end of the second PCB. The second PCB includes one or more connectors at a second end, opposite the first, for connecting to the backplane of the rack server. The backplane is coupled to a motherboard within the rack server.

### BACKGROUND

### Field of the Invention

This invention relates to systems and methods for mounting SSD modules to a server.

### Background of the Invention

Many server systems, such as a typical rack-mounted server, include several bays into which hot-swappable hard disk drive (HDD) may be inserted. However, solid state drive (SSD) storage has many advantages over HDD, principally lower latency.

The apparatus disclosed herein provides an improved approach for using SSD storage in a server system.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIG. 1 is an isometric view of a rack server having modular SSD installed therein in accordance with an embodiment of the present invention;

FIG. 2 is an isometric view of a backplane for a rack server in accordance with an embodiment of the present invention;

FIG. 3 is a schematic block diagram of a rack server and the modular SSD in accordance with an embodiment of the present invention;

FIG. 4A is s rear isometric view of the modular SSD in accordance with an embodiment of the present invention;

FIG. 4B is a rear elevation view of the modular SSD in accordance with an embodiment of the present invention;

FIG. 4C is a front isometric view of the circuit boards of the modular SSD in accordance with an embodiment of the present invention;

FIG. 4D is s front isometric view of the modular SSD drive in accordance with an embodiment of the present invention;

FIG. 5A is a schematic diagram of a bottom circuit board of the modular SSD in accordance with an embodiment of the present invention;

FIG. 5B is a schematic diagram of a top circuit board of the modular SSD in accordance with an embodiment of the present invention;

FIG. 5C is a schematic diagram illustrating the combined top and bottom circuit boards of the modular SSD in accordance with an embodiment of the present invention; and

FIG. 6 is an isometric view showing the modular SSD connected to the back plane of the rack server in accordance with an embodiment of the present invention;

FIG. 7 is a schematic block diagram of a computing device that may be implemented using the rack server; and

FIG. 8 is a schematic block diagrams of a components of an SSD.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

The invention has been developed in response to the present state of the art and, in particular, in response to the problems and needs in the art that have not yet been fully solved by currently available apparatus and methods.

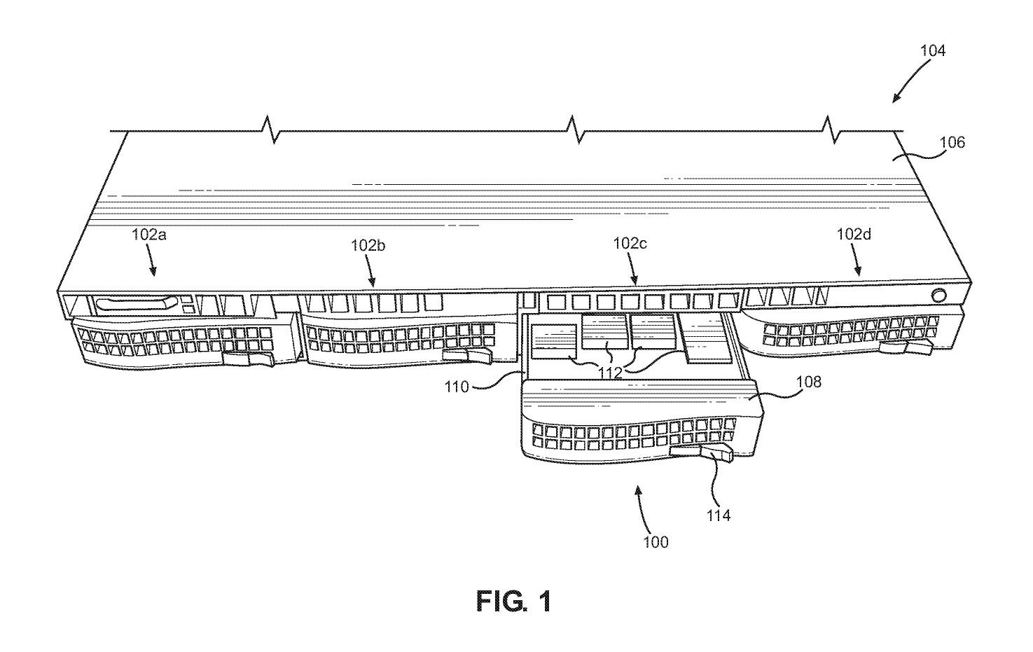

Referring to FIG. 1, a modular SSD 100 as described herein may be used in the place of a modular HDD. In particular, the modular SSD 100 may be use as a “hot-swappable” modular drive that may be installed in and removed from one of a plurality of bays 102a-102d of rack server 104. In particular, the bays 102a-102d may be configured to receive a modular HDD such that a modular HDD may be removed from a bay 102a-102d and replaced with a modular SSD 100 as described herein without any modification.

The bays 102a-102d may be defined by the chassis 106 of the rack server 104 such that openings to the bays 102a-102d are exposed and accessible without opening the chassis 106 or otherwise disassembling the rack server 104. Each modular SSD 100 may include a graspable handle 108 that is exposed when the modular SSD 100 is installed in one of the bays 102a-102d.

Each modular SSD 100 further includes a frame 110 having flash storage modules 114 (“storage modules 112”) mounted thereto. The handle 108 is fastened to the frame and is exposed when the frame is inserted into one of the bays 102a-102d. The structure of the frame 110 and the storage modules 112 are described in greater detail below. The flash storage module 112 include solid state storage chips, such as NAND flash or other type of persistent solid state storage technology. Fore example, the flash storage modules 112 may be PCI-E Gen 3 M.2 NVMe SSD modules.

A latch release 114 may be mounted to the frame and exposed along with the handle 108 when the frame is inserted within one of the bays 102a-102d. The latch release 114 may be actuated by an operator to release a latching mechanism (not shown) securing the frame 110 within the bay 102a-102d. The latching mechanism and latch release 114 may be configured in any manner known in the art for implementing hot-swappable storage modules for a rack server, including for module HDD drives.

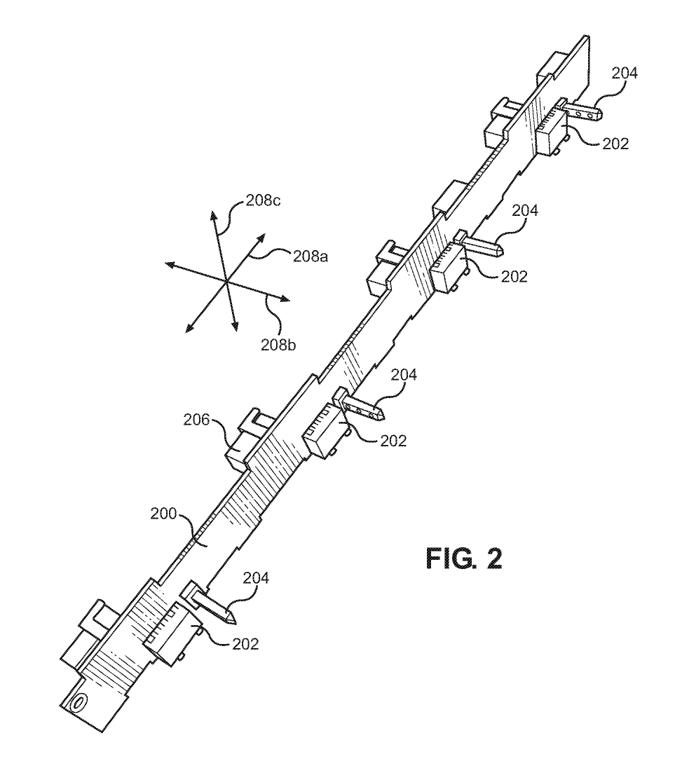

Referring to FIG. 2 a backplane 200 may be mounted within the chassis 106 and span across the bays 102a-102d. The backplane 200 may be embodied as a printed circuit board (PCB) and includes connectors corresponding to each bay 102a-102d.

For example, a data connector 202 may protrude from a first side of the backplane 200 for each bay 102a-102d. The data connector 202 may be embodied as a J7 connector, a high speed board-to-board connector (e.g. AirMAX VSe connector), standard PCIe (Peripheral Component Interconnect Express), Gen 3 x8 bus, GPIO (general purpose input output) implementing control signals and DC power, or other type of data connector. The data connector 202 may include at least one pin supplying DC (direct current) power to a modular SSD drive 100 coupled to the connector 202. The data connector 202 may include at least one pin providing a ground connection to the modular SSD drive 100. The data connector also includes one or more lines for exchanging data with the modular SSD drive 100.

In some embodiments, additional mechanical connectors 204 protrude from the first side of the backplane 200 at positions corresponding to the bays 102a-102d. In the illustrated embodiment, each mechanical connector 204 is positioned adjacent a corresponding data connector 202 for a particular bay 102a-102d. The mechanical connector 204 may provide a tapered guide pin that facilitates alignment of the data connector 204 with a corresponding connector on the modular SSD drive 100. In the illustrated embodiment, the mechanical connector 204 is embodied as a J10 connector. The mechanical connector 204 may facilitate hot swappable functions of the modular SSD drive 100.

Motherboard connectors 206 may be mounted to a second side of the backplane 200, the second side being opposite the first side. The motherboard connectors 206 may be any of the connector types listed above for the data connector 202. Cables may couple the motherboard connectors 206 to a motherboard of the rack server 104 in order to enable a CPU of the motherboard to access the modular SSD drives 100. Each motherboard connector 206 is coupled to one of the data connectors 202. For example, the backplane 200 may implement a circuit board to which the connectors 202, 206 are soldered and which provides an electrical connection between each data connector 202 and a corresponding one of the motherboard connectors 206. In some embodiments, the backplane 200 is implemented as part of the motherboard such that the motherboard connectors 206 may be omitted.

The backplane 200 may be understood with respect to the following directions that are mutually orthogonal: a horizontal direction 208a, a longitudinal direction 208b, and a vertical direction 208c. Note that these directions are labeled in order to facilitate the understanding of the relative locations and function of elements but may not correspond to the actual orientation of the device in use, i.e. the rack server 104 may be placed in a vertical or horizontal orientation.

The data connectors 202 and mechanical connectors 204 are distributed along the horizontal direction 208a and protrude from the first side of the back plane 200 in the longitudinal direction 208b. Accordingly, insertion and removal of a module is performed by movement substantially (e.g., within 5 degrees) along the longitudinal direction 208b. As shown in FIG. 2, the mechanical connector 204 may protrude from the first side of the backplane 200 in the longitudinal direction 208 to a greater extent than the data connector 202, e.g. between 1.5 and 3 times as much. Accordingly, the modular SSD 100 engages the mechanical connector 204, which then constrains the modular SSD 100 to align with the data connector 202 as the modular SSD 100 is moved closer to the back plane. As shown, the mechanical connector is tapered, i.e. narrows with distance along the longitudinal direction 208b from the backplane 200 in order to facilitate engagement with the modular SSD drive 100.

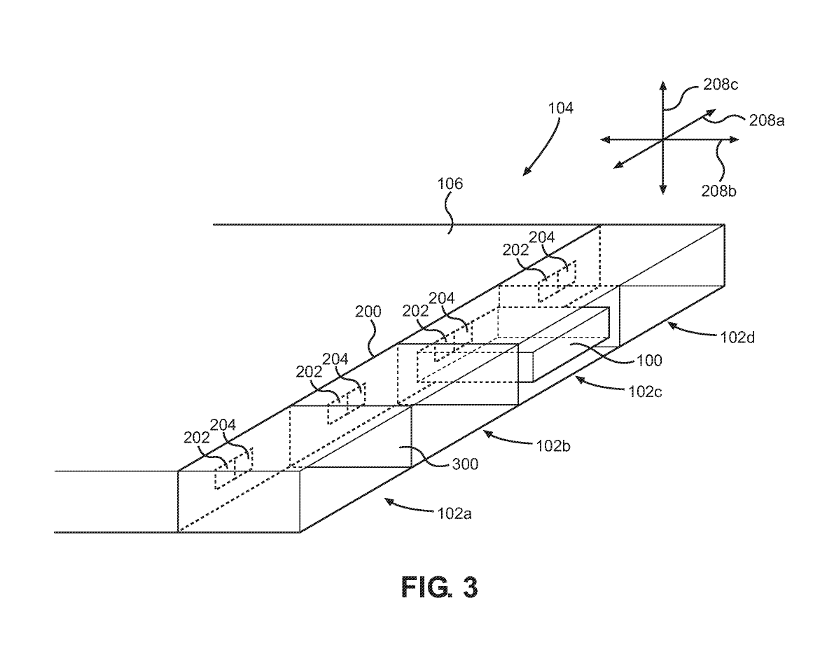

FIG. 3 is a schematic diagram illustrating the function of the backplane 200 with respect to the modular SSD 100. The back plane 200 has a portion positioned at the back of each of the bays 102a-102d such that a connector 202 and a connector 204 are positioned at the back of each bay 102a-102d. A modular SSD 100 may then be inserted into a bay 102a-102d into engagement with the connectors 202, 204. Bays 102a-102d may be separated from one another by a barrier 300 that may be embodied as a wall of metal, plastic, or one or more cross member of metal or plastic that separate the bays 102a-102d from one another.

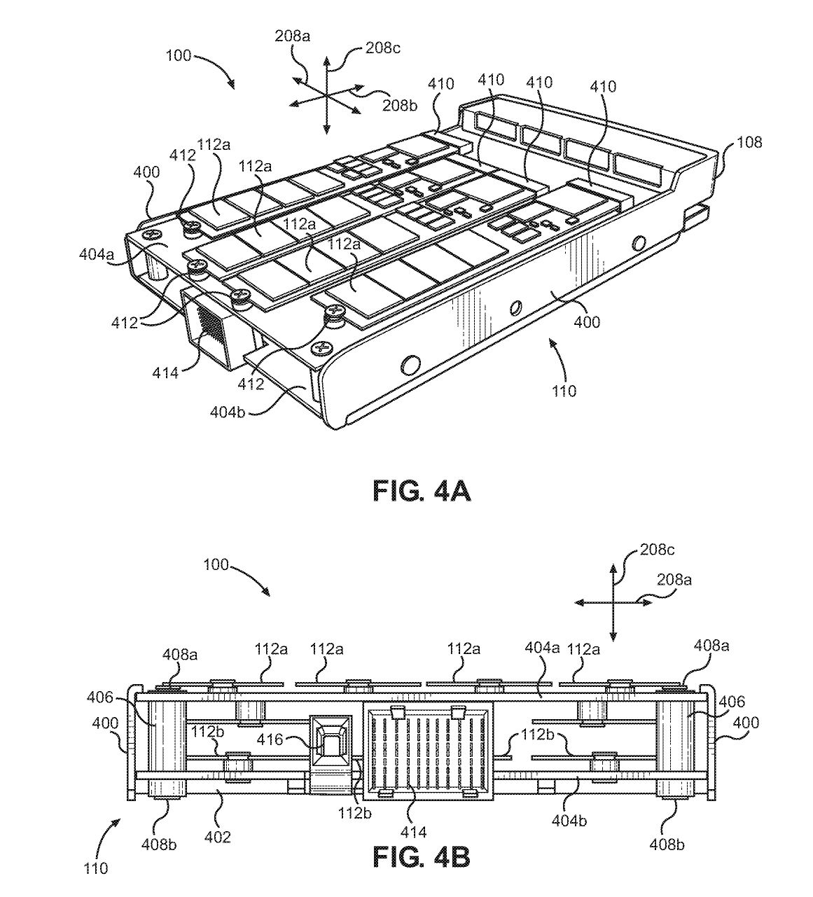

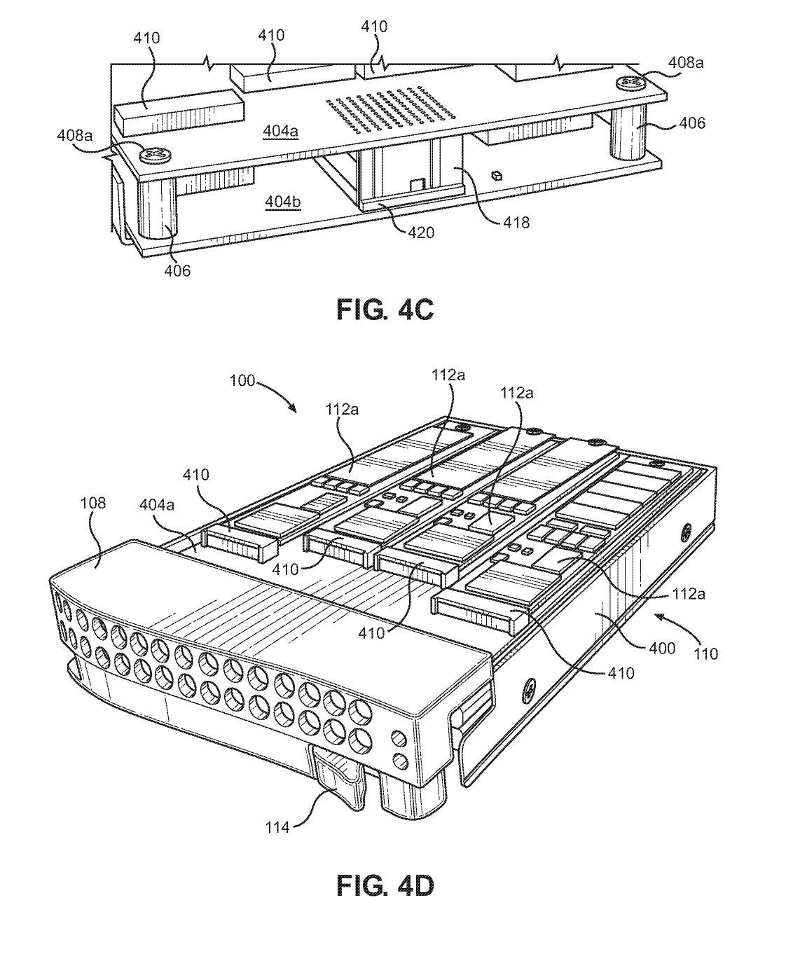

Referring to FIG. 4A, the frame 110 may include side plates 400 that extend along the modular SSD 100 in the longitudinal and vertical directions 208b, 208c. The side plates 400 may fasten or be monolithically formed with a base 402, which may be embodied as a plate or one or more cross members secured to the side plates 400.

One or more PCBs 404a, 404b mount to the frame 110. In the illustrated embodiment, there are two PCBs 404a, 404b. The PCBs 404a are mounted in the frame 110 offset from one another in the vertical direction 208c and substantially overlapping one another in the horizontal and longitudinal directions 208a, 208b. The PCBs 404a, 404b are positioned between the side plates 400. In the illustrated embodiment, posts 406 are positioned between the PCBs 404a, 404b and are fastened to the PCBs 404a, 404b. The posts 406 may be distributed throughput a space between the PCBs 404a, 404b such as at four or more locations between the PCBs 404a, 404b. In the illustrated embodiments, the posts 406 are positioned near the corners of the PCBs 404a, 404b. In the illustrated embodiment, the PCB 404b is also fastened to the base 402. For example, fasteners 408a secure the first PCB 404a to the posts 406. Fasteners 408b pass through the base 402 and second PCB 404b and engage the posts 406.

Each PCB 404b may have one or more flash storage modules mounted thereto. For example, PCB 404a may have four flash storage modules 112a mounted thereto and PCB 404 may have four flash storage modules 112b. The number of modules 112a, 112b on each PCB 404a, 404b may be the same or different and may be any number permitted by the size of the PCB 404a, 404b, such as any number from one to eight.

In the illustrated example, each PCB 404a, 404b may define sockets 410 that receive the flash storage modules 112a, 112b mounted to that PCB 404a, 404b. Additional fasteners 412 may be used to secure the flash storage modules 112a, 112b to the PCBs 404a, 404b, such as at an opposite end of the flash storage module 112a, 112b from the socket 410.

In the illustrated embodiment, the flash storage modules 112a, 112b are placed on the sides of the PCBs 404a, 404b facing in the same direction. For example, if the base 402 secures to a bottom of PCB 404b, the flash storage modules 112a, 112b may mount to the top sides of the PCBs 404a, 404b. In an alternative approach, the surfaces of the PCBs 404a, 404b having the flash storage modules 112a, 112b mounted thereto may face toward one another. In some embodiments, one or both of the PCBs 404a, 404b may include flash storage modules 112a, 112b mounted to both top and bottom surfaces thereof. For example, PCB 404a does not include a surface fastened to the base, and therefore both surfaces of PCB 404a, may have flash storage modules 112a, 112b mounted thereto in some embodiments.

A data connector 414 configured to mate with the data connector 202 may be mounted to a rear edge of one of the PCBs 404a, 404b. The data connector 414 may therefore be a corresponding portion of the fastener type of the data connector 202. For example, the data connector 202 may be a male portion of a fastener type whereas the data connector 414 is the female portion of the fastener type, or vice versa. In the illustrated embodiment, the data connector 414 mounts to the bottom PCB 404b. A mechanical connector 416 configured to engage the mechanical connector 204 may also mount to one of the PCBs 404a, 404b or to some portion of the frame 110. For example, the mechanical connector 416 may be a socket sized to receive the mechanical connector 204 and mounted to the bottom PCB 404b or to the base 402. The socket may be tapered corresponding to the tapered shape of the connector 204, e.g. be wider at the opening of the socket and narrow with distance from the opening.

Referring specifically to FIG. 4C, in the illustrated embodiment the data connector 414 is placed on one of the PCBs 404b and access to the other PCB 404a and its flash storage modules 112a may be performed through a connection between them. For example, PCB 404a may include a first data connector 418 and PCB 404b may include a second data connector 420 configured to mate with the connector 418. The first and second data connectors 418, 420 may be of any of the connector types listed above for the data connector 402. When assembled, the first connector 418 is engaged with the second connector 420 thereby providing a data connection between the PCBs 404a, 404b. In the illustrated embodiment, the data connectors 418, 420 are positioned at an edge of the PCBs 404a, 404b opposite the data connector 414, e.g., the front edge in the illustrated embodiment. Accordingly, one or more storage modules 112b may be mounted to PCB 404b between the data connector 414 and the data connector 420.

As shown in FIG. 4D, the handle 108 may mount to the frame at the front end thereby covering the edges of the PCBs 404a, 404b and the connectors 418, 420.

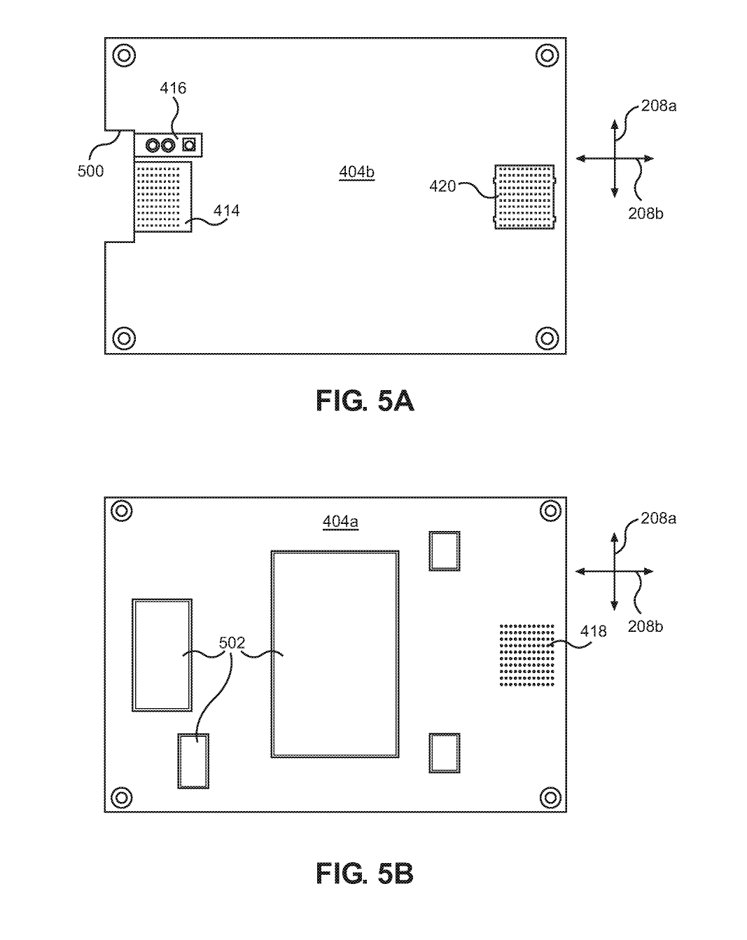

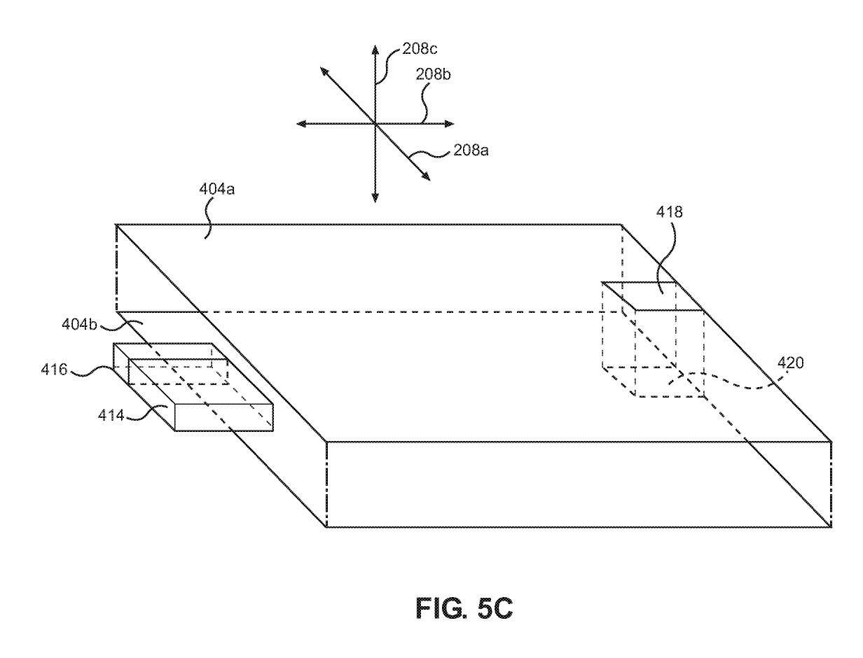

FIGS. 5A to 5C provide alternative views of the configuration of the PCBs 404a, 404b. As shown in FIG. 5A, the PCB 404b may have the connectors 414, 416 mounted to a rear edge thereof and may define a notch 500 such that the position of the rear edge of connectors 414, 416 is offset inwardly from the rearward most edge of the PCB 404b. As shown in FIG. 5A, the connector 420 may be positioned at an opposite edge of the PCB 404b such that there is a space between the connector 420 and the connectors 414, 416 to place a flash storage module 112b.

As shown in FIG. 5B, the PCB 404a may lack the connectors 414, 416 to connect to the connectors 202, 204 of the backplane 200 but include a connector 418 for mating with the connector 420. As shown, the connector 420 is positioned to engage with the connector 418 when the PCBs 404a, 404b are positioned aligned with one another in the horizontal and longitudinal directions 208a, 208b.

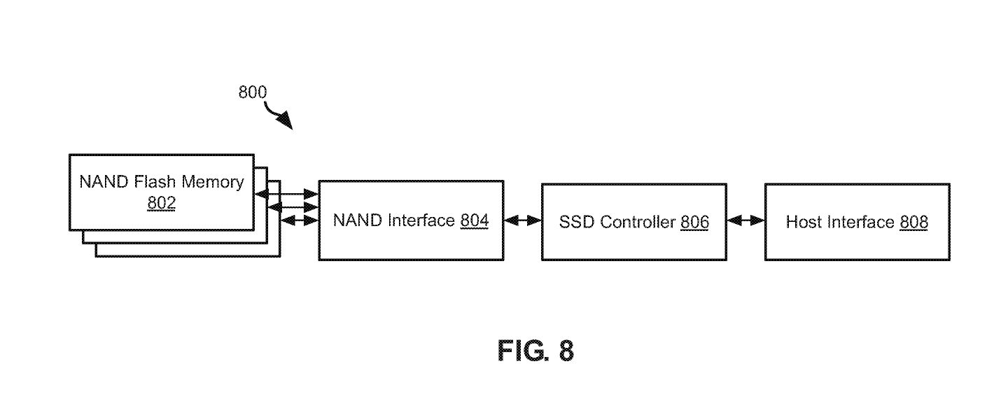

In the illustrated embodiment, a chipset 502 may be mounted to the PCB 404a, such as to the bottom surface (opposite the flash storage modules 112a). The chipset 502 may implement control functions for the modular SSD 100 (see discussion of FIG. 8, below). In other embodiments, the chipset 502 is mounted to the PCB 404b or distributed across both PCBs 404a, 404b.

The relative orientation of the connectors 414, 416 and connectors 418, 420 is further represented in the schematic illustration of FIG. 5C, which shows the connectors 418, 420 engaged with one another and the connectors 414, 416 positioned to engage the connectors 202, 204 of the backplane 200.

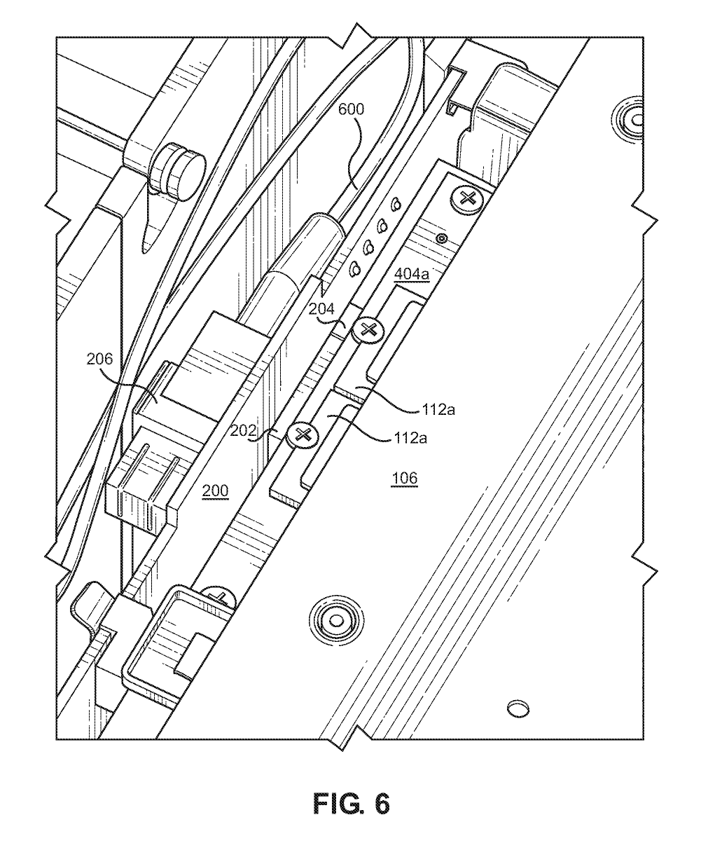

Referring to FIG. 6, in use the modular SSD 100 is inserted into a bay 102a-102d and is slid until the connectors 414, 416 engage the connectors 202, 204 as shown. As is apparent in FIG. 6, the motherboard connectors 206 may connect to cables 600 that are coupled to a motherboard (not shown) mounted in the chassis 106.

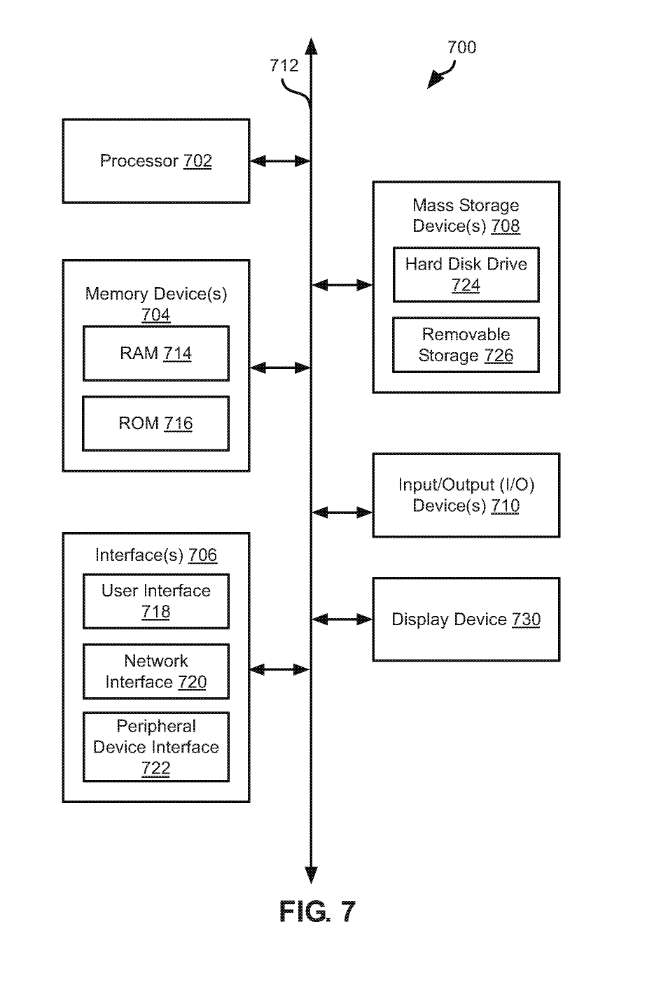

FIG. 7 is a block diagram illustrating an example computing device 700. The rack server 104 may be part of such a computing device 700. In particular, the motherboard mounted in the chassis 106 and coupled to the motherboard connectors 206 may include some or all of the components of the computing device 700

The motherboard may include one or more processor(s) 702, one or more memory device(s) 704 and one or more interface(s) 706. Coupled to the processor 702 by way of the motherboard may be one or more mass storage device(s) 708 (e.g., the modular SSDs 100), one or more Input/Output (I/O) device(s) 710, and a display device 730 all of which may be coupled to a bus 712 of the motherboard. Processor(s) 702 include one or more processors or controllers that execute instructions stored in memory device(s) 704 and/or mass storage device(s) 708. Processor(s) 702 may also include various types of computer-readable media, such as cache memory.

Memory device(s) 704 include various computer-readable media, such as volatile memory (e.g., random access memory (RAM) 714) and/or nonvolatile memory (e.g., read-only memory (ROM) 716). memory device(s) 704 may also include rewritable ROM, such as flash memory.

Mass storage device(s) 708 include various computer readable media, such as magnetic tapes, magnetic disks, optical disks, solid-state memory (e.g., flash memory), and so forth. As shown in FIG. 7, a particular mass storage device is a hard disk drive 724. Various drives may also be included in mass storage device(s) 708 to enable reading from and/or writing to the various computer readable media. Mass storage device(s) 708 include removable media 726 and/or non-removable media.

I/O device(s) 710 include various devices that allow data and/or other information to be input to or retrieved from computing device 700. Example I/O device(s) 710 include cursor control devices, keyboards, keypads, microphones, monitors or other display devices, speakers, printers, network interface cards, modems, lenses, CCDs or other image capture devices, and the like.

Display device 730 includes any type of device capable of displaying information to one or more users of computing device 700. Examples of display device 730 include a monitor, display terminal, video projection device, and the like.

interface(s) 706 include various interfaces that allow computing device 700 to interact with other systems, devices, or computing environments. Example interface(s) 706 include any number of different network interfaces 720, such as interfaces to local area networks (LANs), wide area networks (WANs), wireless networks, and the Internet. Other interface(s) include user interface 718 and peripheral device interface 722. The interface(s) 706 may also include one or more user interface elements 718. The interface(s) 706 may also include one or more peripheral interfaces such as interfaces for printers, pointing devices (mice, track pad, etc.), keyboards, and the like.

Bus 712 allows processor(s) 702, memory device(s) 704, interface(s) 706, mass storage device(s) 708, and I/O device(s) 710 to communicate with one another, as well as other devices or components coupled to bus 712. Bus 712 represents one or more of several types of bus structures, such as a system bus, PCI bus, IEEE 1394 bus, USB bus, and so forth.

For purposes of illustration, programs and other executable program components are shown herein as discrete blocks, although it is understood that such programs and components may reside at various times in different storage components of computing device 700, and are executed by processor(s) 702. Alternatively, the systems and procedures described herein can be implemented in hardware, or a combination of hardware, software, and/or firmware. For example, one or more application specific integrated circuits (ASICs) can be programmed to carry out one or more of the systems and procedures described herein.

Referring to FIG. 8, a typically flash storage system 800 includes a solid state drive (SSD) may include a plurality of NAND flash memory devices 802. One or more NAND devices 802 may interface with a NAND interface 804 that interacts with an SSD controller 806. The SSD controller 806 may receive read and write instructions from a host interface 808 implemented on or for a host device, such as a device including some or all of the attributes of the computing device 700. The host interface 808 may be a data bus, memory controller, or other components of an input/output system of a computing device, such as the computing device 700 of FIG. 7.

Some or all of the components 802-808 may be housed in the modular SSD drive 10. Alternatively, some of the components, such as the host interface 808 may be implemented on a motherboard of the computing device 700. As noted, the components 802-808 may be implemented by the chipset 502 mounted to one of the PCBs 404a, 404b.

The present invention may be embodied in other specific forms without departing from its spirit or essential characteristics. The described embodiments are to be considered in all respects only as illustrative, and not restrictive. In particular, although the methods are described with respect to SSD storage, other types of storage may also benefit from the methods disclosed herein. The scope of the invention is, therefore, indicated by the appended claims, rather than by the foregoing description. All changes which come within the meaning and range of equivalency of the claims are to be embraced within their scope.

What is claimed is:

1. A storage module comprising:
a frame defining a front end and a rear end;
a first printed circuit board mounted to the frame and extending between the front end and the rear end, the first printed circuit board having first solid state storage devices mounted thereto; and
a second printed a second printed circuit board mounted to the frame and extending between the front end and the rear end, the second printed circuit board having second solid state storage devices mounted thereto;
wherein a first connector is coupled to the first printed circuit board at the front end and a second connector is coupled to the first printed circuit board between the first solid state storage devices and the rear end;
wherein a third connector is coupled to the second printed circuit board at the rear end and engages the second connector; and
wherein the first and second circuit boards define circuits configured to enable access to the first solid state storage devices and the second solid state storage devices through the first connector.

2. The storage module of claim 1, wherein:
the first printed circuit board has an upper surface and a lower surface;
the second printed circuit board has an upper surface and a lower surface, the lower surface of the second printed circuit board facing the upper surface of the first printed circuit board;
the first solid state storage devices are mounted to the upper surface of the first printed circuit board; and
the second solid state storage devices are mounted to the upper surface of the second printed circuit board.

3. The storage module of claim 2, wherein:
the second connector is mounted to the upper surface of the first printed circuit board; and
the third connector is mounted to the lower surface of the second printed circuit board.

4. The storage module of claim 2, wherein the frame comprises:
a base, the lower surface of the first circuit board engaging the base;
a first side secured to a first edge of the base and extending outwardly therefrom, the first edge extending between the front end and the rear end; and
a second side secured to a second edge of the base and extending outwardly therefrom, the second edge extending between the front end and the rear end and positioned opposite the first edge;
wherein the first printed circuit board and second printed circuit board are positioned between the first side and the second side.

5. The storage module of claim 2, further comprising a plurality of offset posts secured between the upper surface of the first printed circuit board and the lower surface of the second printed circuit board.

6. The storage module of claim 1, wherein the first connector is a J10 connector.

7. The storage module of claim 6, further comprising a fourth connector secured to the first printed circuit board at the front end adjacent the first connector, the fourth connector comprising a J7 connector.

8. The storage module of claim 1, further comprising a handle secured to the frame and covering the rear end.

9. A server system comprising:
a chassis defining a plurality of bays;
a backplane extending across the plurality of bays and including a plurality of backplane connectors, each backplane connector of the plurality of backplane connectors positioned in a corresponding bay of the plurality of bays;
a motherboard mounted within the chassis and operably coupled to the backplane;
a plurality of storage modules, each storage module of the plurality of storage module positioned within a bay of the plurality of bays and comprising:
a frame defining a front end and a rear end;
a first printed circuit board mounted to the frame and extending between the front end and the rear end, the first printed circuit board having first solid state storage devices mounted thereto; and
a second printed a second printed circuit board mounted to the frame and extending between the front end and the rear end, the second printed circuit board having second solid state storage devices mounted thereto;
a first connector coupled to the first printed circuit board at the front end and a second connector is coupled to the first printed circuit board between the first solid state storage devices and the rear end, the first connector engaging one of the backplane connectors of the plurality of backplane connectors;
a third connector coupled to the second printed circuit board at the rear end and engages the second connector; and
wherein the first and second circuit boards define circuits configured to enable access to the first solid state storage devices and the second solid state storage devices through the first connector.

10. The server system of claim 9, wherein for each storage module of the plurality of storage modules:
the first printed circuit board has an upper surface and a lower surface;
the second printed circuit board has an upper surface and a lower surface, the lower surface of the second printed circuit board facing the upper surface of the first printed circuit board;
the first solid state storage devices are mounted to the upper surface of the first printed circuit board; and
the second solid state storage devices are mounted to the upper surface of the second printed circuit board.

11. The server system of claim 10, wherein for each storage module of the plurality of storage modules:
the second connector is mounted to the upper surface of the first printed circuit board; and
the third connector is mounted to the lower surface of the second printed circuit board.

12. The server system of claim 10, wherein for each storage module of the plurality of storage modules:
the frame comprises:
a base, the lower surface of the first circuit board engaging the base;
a first side secured to a first edge of the base and extending outwardly therefrom, the first edge extending between the front end and the rear end; and
a second side secured to a second edge of the base and extending outwardly therefrom, the second edge extending between the front end and the rear end and positioned opposite the first edge;
wherein the first printed circuit board and second printed circuit board are positioned between the first side and the second side.

13. The server system of claim 10, wherein each storage module of the plurality of storage modules further comprises a plurality of offset posts secured between the upper surface of the first printed circuit board and the lower surface of the second printed circuit board.

14. The server system of claim 9, wherein the first connector and the plurality of backplane connectors are a J10 connector.

15. The server system of claim 14, wherein each storage module of the plurality of storage modules further comprises a fourth connector secured to the first printed circuit board at the front end adjacent the first connector, the fourth connector comprising a J7 connector, the backplane further comprising a plurality of J8 connectors, the J7 connector of each storage module engaging one of the plurality of J8 connectors.

16. The server system of claim 9, wherein each storage module of the plurality of storage modules further comprises a handle secured to the frame and covering the rear end.

17. A method comprising:
providing a server system comprising:
a chassis defining a plurality of bays;
a backplane extending across the plurality of bays and including a plurality of backplane connectors, each backplane connector of the plurality of backplane connectors positioned in a corresponding bay of the plurality of bays; and
a motherboard mounted within the chassis and operably coupled to the backplane;
removing a first storage module from a first bay of the plurality of bays, the first storage module including a hard disk drive (HDD);
inserting a second storage module in the first bay in engagement with the backplane connector of the plurality of backplane connectors corresponding to the first bay, the second storage module comprising one or more circuit boards having a plurality of solid state storage devices mounted thereto.

18. The method of claim 1, wherein the second storage module comprises:
a frame defining a front end and a rear end;
a first printed circuit board mounted to the frame and extending between the front end and the rear end, the first printed circuit board having first solid state storage devices of the plurality of solid state storage devices mounted thereto; and
a second printed a second printed circuit board mounted to the frame and extending between the front end and the rear end, the second printed circuit board having second solid state storage devices of the plurality of solid state storage devices mounted thereto;
a first connector coupled to the first printed circuit board at the front end and a second connector is coupled to the first printed circuit board between the first solid state storage devices and the rear end, the first connector engaging one of the backplane connectors of the plurality of backplane connectors;
a third connector coupled to the second printed circuit board at the rear end and engages the second connector; and
wherein the first and second circuit boards define circuits configured to enable access to the first solid state storage devices and the second solid state storage devices through the first connector.

19. The method of claim 18, wherein:
the first printed circuit board has an upper surface and a lower surface;
the second printed circuit board has an upper surface and a lower surface, the lower surface of the second printed circuit board facing the upper surface of the first printed circuit board;
the first solid state storage devices are mounted to the upper surface of the first printed circuit board; and
the second solid state storage devices are mounted to the upper surface of the second printed circuit board.

20. The server system of claim 19, wherein for each storage module of the plurality of storage modules:
the second connector is mounted to the upper surface of the first printed circuit board; and
the third connector is mounted to the lower surface of the second printed circuit board.
